(19) United States
(12) Patent Application Publication
(10) Pub. No.: US 2019/0097078 A1
(43) Pub. Date: Mar. 28, 2019

(54) Solar cell with doped polysilicon surface areas and method for manufacturing thereof

(71) Applicant: Stichting Energieonderzoek Centrum Nederland, Petten (NL)

(72) Inventors: Lambert Johan Geerligs, Petten (NL); Paula Catharina Petronella Bronsveld, Petten (NL); Yu Wu, Petten (NL)

(73) Assignee: Stichting Energieonderzoek Centrum Nederland, Petten, OT (NL)

(21) Appl. No.: 16/082,943

(22) PCT Filed: Mar. 7, 2017
(86) PCT No.: PCT/NL2017/050138

§ 371 Date: Sep. 7, 2018

(30) Foreign Application Priority Data
Mar. 7, 2016 (NL) 2016382

(51) Int. Cl. H01L 31/18; H01L 31/0368

(52) U.S. Cl. CPC H01L 31/182; H01L 31/03682

(57) ABSTRACT

A method for manufacturing a front floating emitter type solar cell includes providing a silicon substrate of a first or second conductivity type with a front surface and a rear surface; creating a tunneling oxide layer on the rear surface of the silicon substrate; depositing a polysilicon layer on at least the rear surface; creating a doped area of the first conductivity type in an area part of the polysilicon layer on the rear surface;

forming in or on the front surface a doped layer of the second conductivity type opposite to the first conductivity type. In the area part of the polysilicon layer on the rear surface, a concentration of the impurity of the first conductivity type is larger than a concentration of the impurity of the second conductivity type, and the area part of the polysilicon layer on the rear surface has conductivity of the first conductivity type.

### FIELD OF THE INVENTION

The present invention relates to a method for manufacturing a solar cell with doped polysilicon surface areas. Also, the present invention relates to a solar cell with doped polysilicon surface areas.

### BACKGROUND

From the prior art (e.g. U.S. Pat. No. 7,633,006) it is known that doped polycrystalline silicon (commonly abbreviated as polysilicon or polySi) has favorable properties when used as a semiconductor junction in a solar cell. By combination with a tunnel oxide or other thin dielectric layer between the doped polysilicon and the wafer, a so-called passivated contact or passivating contact can be created, which provides low recombination of electrons and holes at the wafer surface, largely conducts majority carriers, and largely blocks the flow of minority carriers (majority and minority defined with respect to the polarity of the doping of the polysilicon).

As the prior art describes, the thin dielectric layer can be a pure silicon dioxide, silicon oxynitride, or other thin dielectric layer. It can be 1-2 nm thick to allow tunneling, or thicker, e.g. 2.4 nm thermal oxide with containing pinholes to regulate the flow of carriers.

Prior art shows that if such a polysilicon passivated contact is used on the front radiation receiving side of a solar cell, the current from the cell is reduced. Therefore, it has advantages to avoid a polysilicon layer on the front of the solar cell.

From the prior art, a method for manufacturing on a silicon wafer a solar cell with polycrystalline silicon emitter and polysilicon back surface field, BSF, layer is known which comprises a front surface field layer by dopant implantation and diffusion in the front radiation receiving surface or a passivating dielectric coating on the front radiation receiving surface. See for example Yang et al., Appl.Phys.Lett. 108, 033903 (2016).

The method for manufacturing involves a relatively complex process with several and separate masking and implantation steps.

Other work has described the fabrication on one side of a silicon wafer of polysilicon emitter and polysilicon back surface field areas. See for example, U. Römer et al, IEEE Journal of Photovoltaics 5, 507-514 (2015); C. Reichel et al., proceedings of the 29th European Photovoltaic Solar Energy Conference, Amsterdam, Netherlands, 22-26 Sep. 2014, p. 487-491]. The method involves creation of a blanket layer of p-type Boron-doped polysilicon on the rear side, and local overcompensation by masked phosphorous implant and activation anneal. If one would try to combine this with a diffused doped layer in the front surface, complex processing would be required to protect and shield the various active layers during the process steps: For a front floating emitter (Boron doped), complex additional processing and additional thermal steps would be required. Also, this method requires selective removal steps of polysilicon from the floating emitter layer diffused into the surface of the wafer. For a front surface field, the same problems would apply, or the rear side boron-doped polysilicon areas would have to be protected from phosphorous diffusion, which is costly and difficult and requires several additional process steps.

Also, from A. D. Upadhayaya et al, proceedings IEEE PVSC 2015, “Ion implanted screen printed n-type solar cell with tunnel oxide passivated back-contact”, it is known that solar cells of such type provide an improved performance as both the n⁺-doped polysilicon layer and the metal contact are outside the bulk silicon wafer, which causes that the saturation current density Jo is dramatically reduced and results in a much higher open circuit voltage V_{oc}.

It is an object of the present invention to overcome or mitigate one or more of the disadvantages from the prior art.

### SUMMARY OF THE INVENTION

The object is achieved by method for manufacturing a solar cell based on a silicon substrate with a front surface and a rear surface, comprising: on at least the rear surface a polysilicon layer with at least one doped area of a first conductivity type in an area part of the polysilicon layer; on the front surface a doped layer of a second conductivity type opposite to the first conductivity type; the method comprising:—providing a silicon substrate of either the first conductivity type or the second conductivity type and having a front surface and a rear surface;—creating a tunneling oxide layer on at least a rear surface of the silicon substrate;—depositing a polysilicon layer on at least the rear surface;—creating at least one doped area of the first conductivity type in an area part of the polysilicon layer on the rear surface, by exposing the area part to impurity species of the first conductivity type;—forming in or on the front surface a doped layer of the second conductivity type based on exposing the front and rear surfaces of the substrate to impurity species of a second conductivity type opposite to the first conductivity type, in a manner that in the area part of the polysilicon layer on the rear surface, the polysilicon layer comprises impurities of the first conductivity type and impurities of the second conductivity type, in which a concentration of the impurity species of the first conductivity type is larger than a concentration of the impurity species of the second conductivity type, and the area part of the polysilicon layer on the rear surface has a conductivity of the first conductivity type.

According to the invention, the diffusion is controlled to cause only partial compensation of the areas of first conductivity type, such that the areas of first conductivity type remain to have the conductivity characteristics of the first conductivity type. In the areas of the first conductivity type the concentration of activated impurities of the first conductivity type is larger than the concentration of the activated impurities of the second conductivity type. In the other areas of intrinsic polysilicon that are exposed during the diffusion process and were not exposed to ion-implantation with impurities of the first conductivity type, doped areas of the second conductivity type are created. Advantageously, by the all-sided diffusion process, both a front surface emitter layer (or a front surface field layer) and contact areas of second conductivity type are created at the same time.

According to an aspect, the invention provides the method as described above, wherein in the area part of the polysilicon layer on the rear surface, the concentration of the impurity species of the first conductivity type is partially compensated by the concentration of the impurity species of the second conductivity type.

According to an aspect, the invention provides the method as described above, wherein in the deposition step of the polysilicon layer on the at least the rear surface, an intrinsic polysilicon is deposited.

According to an aspect, the invention provides the method as described above, wherein during the deposition step of the polysilicon layer on the at least the rear surface, a doped polysilicon layer of the second conductivity type is deposited.

According to an aspect, the invention provides the method as described above, wherein during the deposition step of the polysilicon layer on the at least the rear surface, a polysilicon layer comprising impurities of the second conductivity type is deposited.

According to an aspect, the invention provides the method as described above, wherein after the deposition of the doped polysilicon layer of the second conductivity type or the polysilicon layer comprising impurities of the second conductivity type, but preceding the creation of the doped areas of the first conductivity type in the area part of the polysilicon layer on the rear surface,

the method comprises:—providing a masking layer area on the rear surface that exposes only the area part of the polysilicon layer with a remainder part of the rear surface being covered by the masking layer area,
and the creation of the doped areas of the first conductivity type in the area part of the polysilicon layer on the rear surface is performed in a manner that in the exposed area part of the polysilicon layer on the rear surface,
a concentration of the impurity of the first conductivity type by exposing the area part to impurity species of the first conductivity type is larger than a concentration of the impurity of the second conductivity type originating from the doped polysilicon layer of the second conductivity type.

According to an aspect, the invention provides the method as described above, wherein after the provision of the masking layer and after the creation of the doped areas of the first conductivity type in the area part of the polysilicon layer on the rear surface, but preceding the formation in the front surface of the doped layer of the second conductivity type, the method additionally comprises: masking partially the doped areas of the first conductivity type and etching trenches in the rear surface of the substrate between the masking layer area and the masked doped area of first conductivity type.

According to an aspect, the invention provides the method as described above, in which the front surface of the substrate is covered at least partially by the polysilicon layer and the method further comprises etching of the polysilicon layer from at least a part of the front surface while etching the trenches in the rear surface.

According to an aspect, the invention provides the method as described above, further comprising: exposing at least a portion of the etched trenches to the impurity species of the second conductivity type and forming in the exposed portion of the etched trenches a doped layer of the second conductivity type.

According to an aspect, the invention provides the method as described above, further comprising simultaneously forming a doped layer of the second conductivity type in the front surface.

According to an aspect, the invention provides the method as described above, further comprising simultaneous formation of a doped layer of the first conductivity type in the front surface.

According to an aspect, the invention provides the method as described above, wherein the formation of the doped layer of the second conductivity type in the front surface includes the formation of the doped layer of the second conductivity type on edges of the silicon substrate.

According to an aspect, the invention provides the method as described above, wherein the area part of the rear surface is substantially equal to the rear surface area of the silicon substrate.

According to an aspect, the invention provides the method as described above, wherein the area part of the rear surface is a patterned area portion.

According to an aspect, the invention provides the method as described above, wherein during the deposition step of the polysilicon layer on the at least the rear surface, a doped polysilicon layer of the second conductivity type is deposited, and the patterned area portion comprises a number of doped areas of first conductivity type, which are interdigitated by intermediate doped areas of the second conductivity type.

According to an aspect, the invention provides the method as described above, wherein the step of creating at least one doped area of the first conductivity type in the area part of the polysilicon layer on the rear surface comprises ion-implantation of impurities of the first conductivity type in the area part of the polysilicon layer on the rear surface.

According to an aspect, the invention provides the method as described above, wherein the step of creating at least one doped area of the first conductivity type in the area part of the polysilicon layer on the rear surface comprises diffusion of impurities of the first conductivity type from a gas phase containing impurities of the first conductivity type into the area part of the polysilicon layer on the rear surface.

According to an aspect, the invention provides the method as described above, wherein only the rear surface or only a portion of the rear surface is exposed to the gas phase containing impurities of the first conductivity type.

According to an aspect, the invention provides the method as described above, wherein the step of creating the at least one doped area of the first conductivity type in the area part of the polysilicon layer on the rear surface, by exposing the area part to impurity species of the first conductivity type is performed simultaneously with the step of depositing the polysilicon layer on at least the rear surface.

According to an aspect, the invention provides the method as described above, wherein the step of exposing the front and rear surfaces of the substrate to impurity species of a second conductivity type comprises diffusion of impurities of the second conductivity type from a gas phase containing impurities of the second conductivity type.

According to an aspect, the invention provides the method as described above, wherein the step of forming in the front surface a doped layer of the second conductivity type based on exposing the front and rear surfaces of the substrate to impurity species of a second conductivity type comprises deposition of a compound containing the impurity species of the second conductivity type from a gas phase.

According to an aspect, the invention provides the method as described above, wherein the first conductivity type is n-type, and the second conductivity type is p-type.

According to an aspect, the invention provides the method as described above, wherein the impurity species of the first conductivity type is one selected from phosphorus, arsenic and antimony.

According to an aspect, the invention provides the method as described above, wherein the impurity species of the second conductivity type is one selected from boron, aluminium, gallium or indium.

According to an aspect, the invention provides the method as described above, wherein the concentration of impurities of the first conductivity type is about 2×10²⁰/cm³ or larger, and the concentration of impurities of the second conductivity type is about 1×10²⁰/cm³ or less.

According to an aspect, the invention provides the method as described above, wherein the ratio between the concentration of impurities of the first conductivity type and the concentration of impurities of the second conductivity type is 1.4 or larger.

Additionally, the invention relates to a solar cell based on a silicon substrate with a front surface and a rear surface, comprising: on at least the rear surface a polysilicon layer with at least one doped area of a first conductivity type in an area part of the polysilicon layer; on the front surface a doped layer of a second conductivity type opposite to the first conductivity type; a tunneling oxide layer between the polysilicon layer and the rear surface of the silicon substrate; the polysilicon layer in the at least one doped area of the first conductivity type comprising first impurity species of the first conductivity type and second impurity species of the second conductivity type, in which a concentration of the first impurity species is larger than a concentration of the second impurity species and the at least one doped area of the polysilicon layer on the rear surface has a conductivity of the first conductivity type.

According to an aspect, the invention provides the solar cell as described above, wherein in the area part of the polysilicon layer on the rear surface, the concentration of the first impurity species of the first conductivity type is partially compensated by the concentration of the second impurity species of the second conductivity type.

According to an aspect, the invention provides the solar cell as described above, further comprising a doped layer of the second conductivity type on edges of the silicon substrate.

According to an aspect, the invention provides the solar cell as described above, wherein the area part of the rear surface is substantially equal to the rear surface area of the substrate.

According to an aspect, the invention provides the solar cell as described above, wherein the rear surface comprises a patterned area portion comprising said at least one doped area of the first conductivity type, and at least one doped area of the second conductivity type adjacent to said at least one doped area of the first conductivity type.

According to an aspect, the invention provides the solar cell as described above, comprising at least one etched trench between the at least one doped area of the first conductivity type and the at least one doped area of the second conductivity type.

According to an aspect, the invention provides the solar cell as described above, wherein the surface of the at least one etched trench comprises a doped layer of second conductivity type.

According to an aspect, the invention provides the solar cell as described above, wherein a remainder portion of the surface of the at least one etched trench is either undoped or comprises a doped layer of the first conductivity type.

Advantageous embodiments are further defined by the dependent claims.

### BRIEF DESCRIPTION OF DRAWINGS

The invention will be explained in more detail below with reference to drawings in which illustrative embodiments thereof are shown. The drawings are intended exclusively for illustrative purposes and not as a restriction of the inventive concept. The scope of the invention is only limited by the definitions presented in the appended claims.

FIGS. 1A-1C show cross-sectional view of a solar cell during manufacturing steps according to an embodiment of the method of the invention;

FIGS. 2A-2C show cross-sectional view of a solar cell during manufacturing steps according to an embodiment of the method of the invention;

FIGS. 3A-3C show cross-sectional view of a solar cell during manufacturing steps according to an embodiment of the method of the invention;

FIGS. 4A-4B show cross-sectional view of a solar cell during manufacturing steps according to an embodiment of the method of the invention;

FIGS. 5A-5B show cross-sectional view of a solar cell during manufacturing steps according to an embodiment of the method of the invention, and

FIGS. 6A-6E show cross-sectional view of a solar cell during manufacturing steps according to an embodiment of the method of the invention.

### DETAILED DESCRIPTION OF EMBODIMENTS

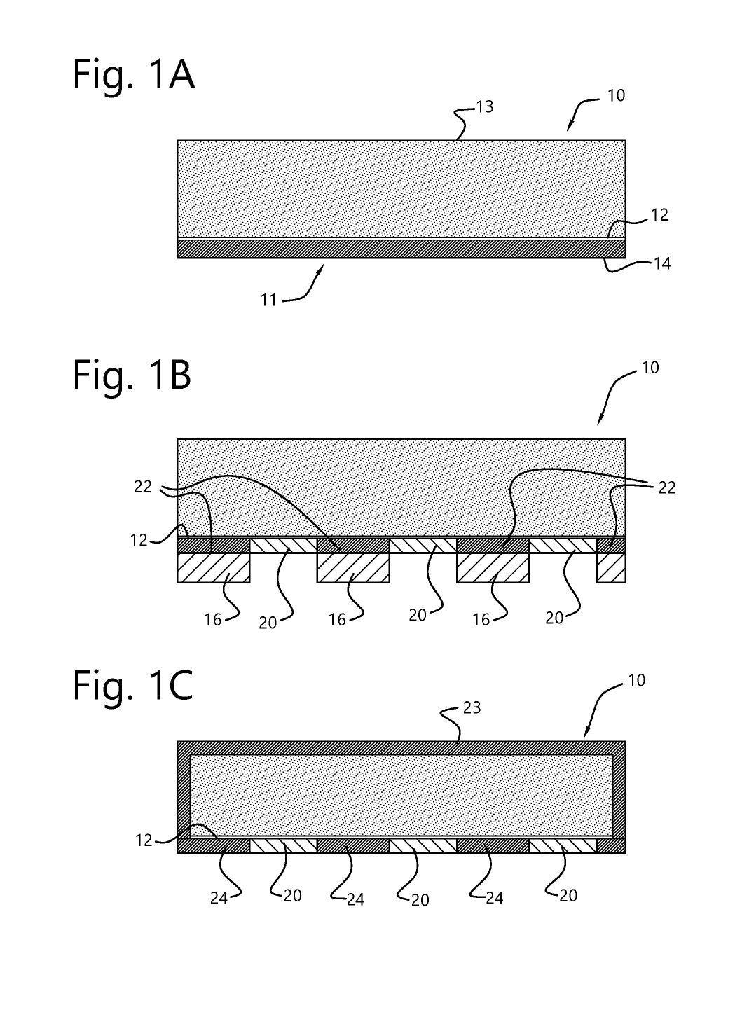

FIGS. 1A-1C show cross-sectional view of a solar cell during manufacturing steps according to an embodiment of the method of the invention.

According to an embodiment, the invention provides a method for manufacturing a front floating emitter (FFE) solar cell with interdigitated back contact (IBC) configuration, i.e., an FFE IBC Solar cell.

As is shown in FIG. 1A: In an initial step of the manufacturing process a silicon substrate 10 is provided. The silicon substrate 10 is a semiconductor, typically monocrystalline and has a base conductivity of a first conductivity type. The first conductivity type can be either n-type or p-type, depending on the type of dopant impurities in the substrate.

In a next step, on at least the rear surface 11 of the silicon substrate 10 a thin film silicon dioxide layer 12 is created. After completion of the solar cell structure, the thin film silicon dioxide layer 12 is arranged to function as a tunneling oxide layer. The thin film silicon dioxide layer 12 has a thickness of 2 nm or less. In some embodiments the thin film silicon dioxide layer 12 is also created on the front surface 13 of the silicon substrate.

The tunneling oxide layer 12 can be created by any process for creating a tunneling thin film silicon dioxide layer 12 as known in the art.

In a subsequent step, a polysilicon layer 14 is created on at least the tunneling silicon dioxide layer 12 on the rear surface 11.

Such a polysilicon layer on the rear surface 11 can be created by a low-pressure chemical vapor deposition (LPCVD) process followed by a single side etch or a single side texture. Note that an LPCVD process will typically deposit the polysilicon layer on both front and rear surfaces of the wafer (i.e., the silicon substrate), and by omitting the use of a single side etch or a single side texture, the polysilicon layer will remain on the front surface 13 of the substrate. Because of the good passivation due to the front side polysilicon layer, the presence of the polysilicon layer on the front surface of the silicon substrate can have advantages for the performance of the solar cell and as shown hereafter it can be applied in several embodiments of the invention.

In the embodiment of FIG. 1A-1C, the deposited polysilicon layer 14 is an intrinsic polysilicon layer. The skilled in the art will appreciate that directly after its deposition, the polysilicon layer 14 may be “proto-crystalline”, that is, the polysilicon layer 14 may be partially amorphous. As the silicon substrate will be exposed to some thermal treatment during following steps of the manufacturing process, the amorphous fraction of the polysilicon layer will crystallize, rendering the polysilicon layer into a polycrystalline silicon layer.

Next, as shown in FIG. 1B, in a masking step, on the rear surface 11 a patterned masking layer 16 is created. The patterned masking layer 16 has a pattern that exposes areas 20 of the polysilicon layer 14 that are to be doped with first conductivity type impurities.

The skilled in the art will appreciate that in the IBC solar cell, the masking pattern is such that in the rear surface 11 an interdigitated pattern of areas of first and second conductivity type is created.

In a subsequent step, the patterned and masked rear surface 11 is exposed to an ion-implantation process that exposes the rear surface 11 to an ion beam comprising impurities of the first conductivity type (for example phosphorous). In this manner, the exposed areas 20 of the polysilicon layer 14 will become, after an anneal treatment, areas 20 of first conductivity type. The areas 22 of the polysilicon layer 14 that are covered by the masking layer 16 remain intrinsic polysilicon.

The skilled in the art will appreciate that as described above and hereafter that after implant or in-situ doping the polysilicon layer 14 is of a certain first or second conductivity type, this should be interpreted as that such a polysilicon layer 14 will be of that certain first or second conductivity type after an anneal treatment to activate dopants and/or enhance crystallization.

In relation to the application of the masking layer 16 in this and the following embodiments, it is noted that for implantation of impurities the masking layer 16 is configured to provide masking up to and including the edge of the wafer. Thus, in some embodiments, the masking layer extends upto the edge of the wafer. Alternatively, the masking layer can be applied nearly upto the edge of the wafer (e.g. upto a distance of about 0.5 mm from the edge) in combination with a mechanical mask positioned above the wafer which blocks the flow of ionized impurities towards or on the remaining edge region (extending e.g. from a distance of about 1.0 mm from the edge until outside of the edge of the wafer). As a further alternative, the method may comprise an emitter edge wrap-around step. In an embodiment, the solar cell comprises a front emitter which wraps around the edges of the silicon substrate to a peripheral portion of the rear surface.

Subsequently, the masking layer 16 is removed, and both the areas 20 of first conductivity type and the areas 22 of intrinsic polysilicon are now exposed.

In FIG. 1C, a cross-section of the silicon substrate 10 is shown after exposing the silicon substrate 10 to an impurity source comprising impurities of a second conductivity type.

In a next step, a diffusion process (or in-diffusion process) is carried out in which the silicon substrate 10 is at elevated temperature while exposed on all sides to the impurity source comprising impurities of a second conductivity type. The impurity source is usually a gas ambient that comprises a gas species containing at least a precursor of the impurities of the second conductivity type (for example BBr₃), but can also be a liquid, a paste or other source.

The second conductivity type is opposite to the first conductivity type. As a result of the all-sided exposure, the impurities of second conductivity type diffuse in all surfaces of the silicon substrate 10.

In the front surface of the silicon substrate 10, a doped layer 23 comprising impurities of the second conductivity type is created as either a front surface emitter layer or a front surface field layer in the solar cell, depending on the conductivity type of the front layer in comparison to the base conductivity type of the silicon substrate 10.

At the same time, the elevated temperature of the diffusion process provides activation of the ion-implanted impurities of first conductivity type.

According to the invention, the diffusion is controlled to cause only partial compensation of the areas 20 of first conductivity type, such that the areas 20 of first conductivity type remain to have the conductivity characteristics of the first conductivity type. In the areas 20 of the first conductivity type the concentration of activated impurities of the first conductivity type is larger than the concentration of the activated impurities of the second conductivity type.

In the other areas 22 of intrinsic polysilicon that are exposed during the diffusion process and were not exposed to ion-implantation with impurities of the first conductivity type, doped areas 24 of the second conductivity type are created.

Advantageously, by the all-sided diffusion process, both a front surface emitter layer (or a front surface field layer) 23 and contact areas 24 of second conductivity type are created at the same time.

According to an exemplary embodiment, the silicon substrate 10 has n-type base conductivity. In the ion implantation step, phosphorous is implanted in the exposed areas 20 on the rear surface 11. During the step of the diffusion process, the silicon substrate 10 is exposed at elevated temperature to an ambient containing at least BBr₃ (boron tribromide) as dopant precursor for Boron as impurity of the second conductivity type. The elevated temperature is typically within a range from about 750° C. to about 950° C. During the diffusion process, the implanted phosphorous is activated.

By controlling the diffusion process, i.e., the diffusion rate of the impurities of the second conductivity type into the silicon substrate 10, the partial compensation in the exposed areas 20 is obtained.

For example, the dopant concentration of phosphorous in the areas 20 of the first conductivity type is equal to or larger than about 2×10²⁰ cm⁻³, while the dopant concentration of boron is equal to or less than about 1×10²⁰ cm⁻³. In this manner, the conductivity characteristics of the impurities of first conductivity type are only partially compensated by the impurities of second conductivity type.

For example, the thickness of the polysilicon layer 14 is between 50 and 200 nm. The thinner thickness of the range is preferred for performance (it gives less optical losses) while the thicker thickness of the range can be helpful to allow metallization by screen-printed firing-through silver thick film pastes without degradation of the passivation. Less than 50 nm thickness is also possible, resulting in even less optical losses, but in practice it can be found that the passivating performance is degraded for such thin layers (like 20 nm thickness), possibly due to degradation of the interfacial barrier or relatively high fraction of oxidation of the polysilicon in subsequent high-temperature process steps.

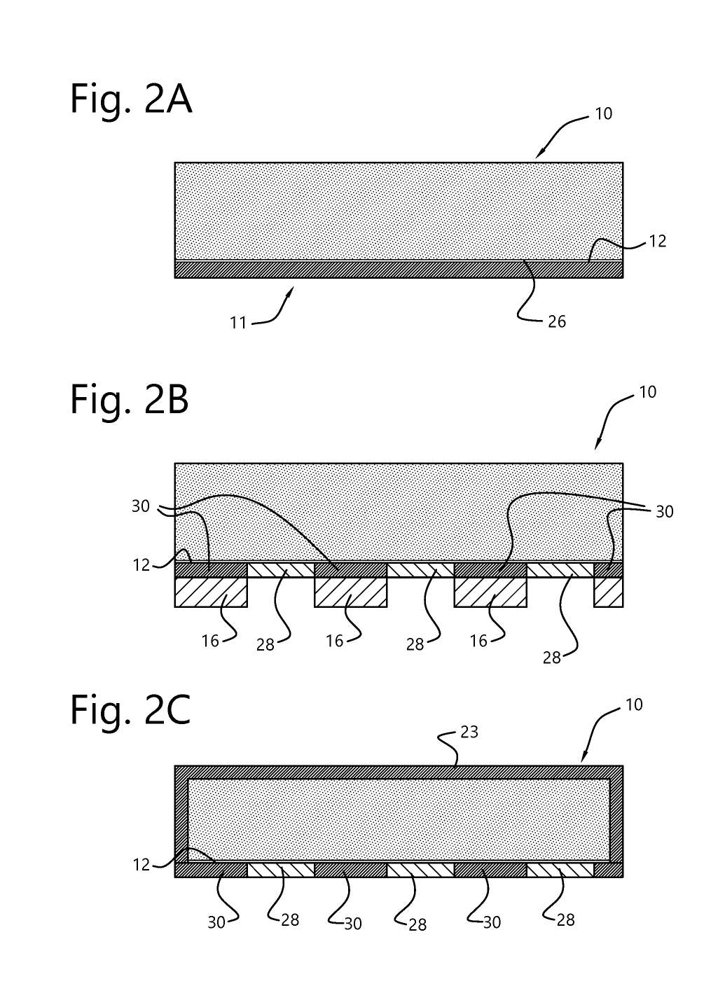

FIGS. 2A-2C show cross-sectional view of a solar cell during manufacturing steps according to an embodiment of the method of the invention.

In FIGS. 2A-2C entities with the same reference number as shown in FIGS. 1A-1C refer to corresponding entities.

Similar as in the embodiment as described above, the method involves the manufacturing of an FFE-IBC solar cell.

In an initial step of the manufacturing process the silicon substrate 10 is provided. The silicon substrate 10 has a base conductivity of a first conductivity type.

In a next step, on the rear surface 11 of the silicon substrate 10 a thin film silicon dioxide layer 12 is created to function as a tunneling oxide layer. The thin film silicon dioxide layer 12 has a thickness of 2 nm or less.

In a subsequent step, a polysilicon layer 26 is created on at least the tunneling oxide layer 12 on the rear surface 11. In this embodiment, the deposited polysilicon layer 26 is a doped polysilicon layer of second conductivity type or contains dopant impurities that when activated in a later process step will result in the second conductivity type.

The polysilicon layer 26 can be created by a low-pressure chemical vapor deposition process followed by a single side etch or a single side texture.

Next, as shown in FIG. 2B, in a masking step, on the rear surface 11 a patterned masking layer 16 is created. The patterned masking layer 16 has a pattern that exposes areas 28 of the polysilicon layer 26 that are to be doped with first conductivity type impurities.

In a subsequent step, the patterned and masked rear surface is exposed to an ion-implantation process that exposes the rear surface 11 to the ion beam comprising impurities of the first conductivity type. The ion-implantation dose is chosen to be sufficiently large that the concentration of the impurities of the first conductivity type is larger than the concentration of impurities of the second conductivity type in the exposed areas 28 of the doped polysilicon layer 26.

In this manner, the exposed areas 28 of the doped polysilicon layer 26 will become areas 28 of first conductivity type after an activation anneal. The areas 30 of the polysilicon layer 26 that are covered by the masking layer 16 remain doped polysilicon of the second conductivity type.

Subsequently, the masking layer 16 is removed, and both the areas 28 of first conductivity type and the areas 30 of second conductivity type polysilicon are now exposed.

In FIG. 2C, a cross-section of the silicon substrate after exposing the substrate to an impurity source comprising impurities of a second conductivity type.

In a next step, an in-diffusion process is carried out in which the silicon substrate 10 is at elevated temperature and is exposed on all sides to the impurity source comprising impurities of the second conductivity type. The impurity source is usually a gas ambient that comprises a gas species containing at least a precursor of the impurities of the second conductivity type.

As a result of the all-sided exposure, the impurities of second conductivity type diffuse in all surfaces of the silicon substrate.

In the front surface of the silicon substrate, a doped layer 23 comprising impurities of the second conductivity type is created as a front surface emitter layer in the solar cell.

According to the invention, the in-diffusion is controlled to cause only partial compensation of the areas 28 of first conductivity type, such that the areas 28 of the first conductivity type remain to have the conductivity characteristics of the first conductivity type. In the areas 28 of the first conductivity type the concentration of impurities of the first conductivity type is larger than the concentration of the impurities of the second conductivity type, after the in-diffusion of the impurities of the second conductivity type.

In the other areas 30 of the doped polysilicon layer 26 of second conductivity type that are exposed during the diffusion process and were not exposed to ion-implantation with impurities of the first conductivity type, doped areas 30 of the second conductivity type are created.

According to an exemplary embodiment, the silicon substrate has n-type base conductivity. In the ion implantation step, phosphorous is implanted in the exposed areas 28 on the rear surface 11. During the diffusion process, the silicon substrate is exposed at elevated temperature to an ambient containing at least BBr₃ (boron tribromide) as dopant precursor for Boron as impurity of the second conductivity type. The elevated temperature is typically within a range from about 750° C. to about 950° C. During the diffusion process, the implanted phosphorous is activated. During the diffusion, dopant impurities in areas 28 may also be activated.

By controlling the diffusion process, i.e., the diffusion rate of the impurities of the second conductivity type into the silicon substrate, the partial compensation in the is obtained.

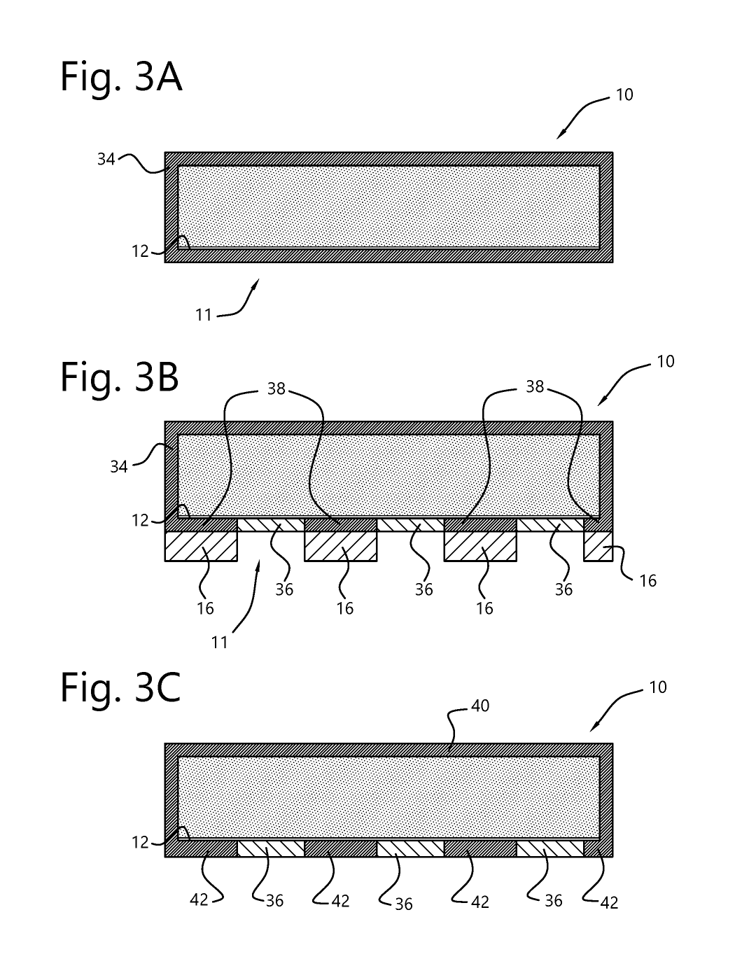

FIGS. 3A-3C show cross-sectional view of a solar cell during manufacturing steps according to an embodiment of the method of the invention.

In FIGS. 3A-3C entities with the same reference number as shown in FIGS. 1A-1C and FIGS. 2A-2C refer to corresponding entities.

Similar as in the embodiment as described above, the method involves the manufacturing of an FFE-IBC solar cell.

In an initial step of the manufacturing process the silicon substrate 10 is provided. The silicon substrate 10 has a base conductivity of a first conductivity type.

In a next step, on the rear surface 11 of the silicon substrate 10 a thin film silicon dioxide layer 12 is created to function as a tunneling oxide layer. The thin film silicon dioxide layer 12 has a thickness of 2 nm or less.

In a subsequent step, a polysilicon layer 34 is created on all sides of the silicon substrate, i.e., front surface, rear surface and edges of the silicon substrate.

Such a polysilicon layer can be created by a low-pressure chemical vapor deposition process. In this embodiment, the deposited polysilicon layer 34 is an intrinsic polysilicon layer.

According to this embodiment, the deposited polysilicon layer 34 is retained on all sides of the substrate during the manufacturing process.

Next, as shown in FIG. 3B, in a masking step, on the rear surface 11 a patterned masking layer 16 is created. The patterned masking layer 16 has a pattern that exposes areas 36 of the polysilicon layer 34 that are to be doped with first conductivity type impurities, while other areas 38 of the polysilicon layer 34 remain covered by the masking layer 16.

Subsequently, the patterned and masked rear surface is exposed to an ion-implantation process that exposes the rear surface 11 to the ion beam comprising impurities of the first conductivity type.

Next, the masking layer 16 is removed, and both the ion-implanted areas 36 of first conductivity type and the areas 38 of intrinsic type polysilicon are now exposed.

In FIG. 3C, a cross-section is shown of the silicon substrate after exposing the substrate to an impurity source comprising impurities of the second conductivity type.

In an in-diffusion process is carried out in which the silicon substrate 10 is at elevated temperature and is exposed on all sides to the impurity source comprising impurities of the second conductivity type.

As a result of the all-sided exposure, the impurities of second conductivity type diffuse in all surfaces of the silicon substrate 10.

In the front surface of the silicon substrate 10, a doped polysilicon layer 40 comprising impurities of the second conductivity type is created as a front surface emitter layer in the solar cell.

According to the invention, the in-diffusion is controlled to cause only partial compensation of the areas 36 of first conductivity type, such that the areas 36 of the first conductivity type remain to have the conductivity characteristics of the first conductivity type. In the areas 36 of the first conductivity type the concentration of impurities of the first conductivity type is larger than the concentration of the impurities of the second conductivity type, after the in-diffusion of the impurities of the second conductivity type.

In the other areas 38 of the intrinsic polysilicon that are exposed during the diffusion process and were not exposed during the ion-implantation with impurities of the first conductivity type, doped areas 42 of the second conductivity type are created.

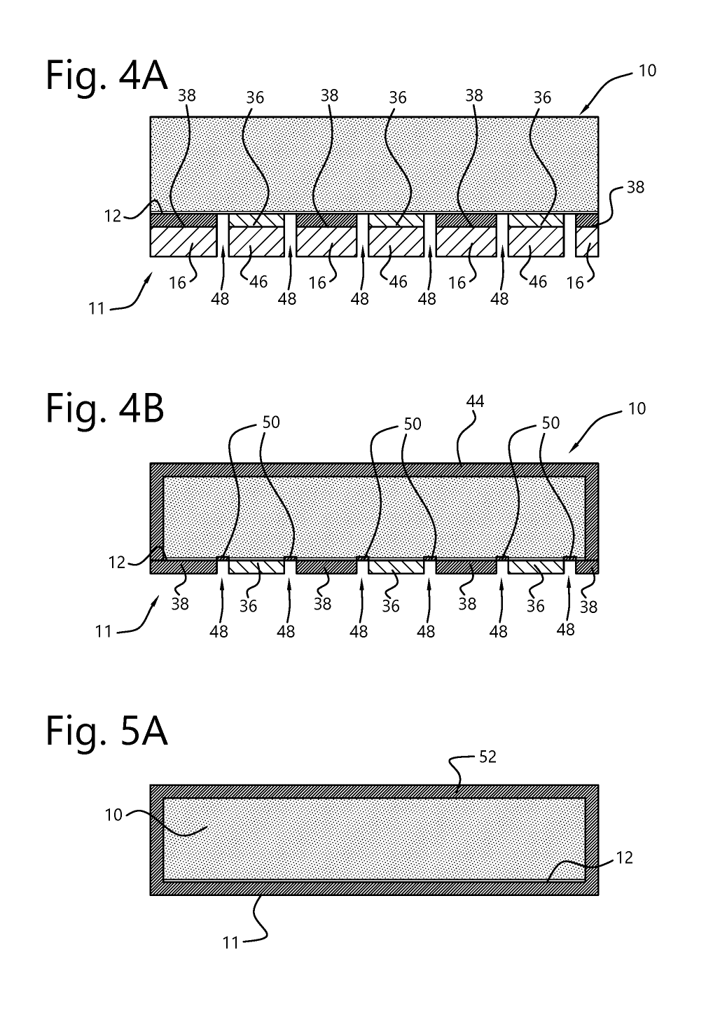

FIGS. 4A-4B show cross-sectional view of a solar cell during manufacturing steps according to an embodiment of the method of the invention.

In FIGS. 4A-4B entities with the same reference number as shown in FIGS. 3A-3C refer to corresponding entities.

As shown in FIG. 4A, after the ion-implantation step to create implanted areas 36 of the first conductivity type in the intrinsic or second conductivity type-doped polysilicon layer 34 (as described above in the method steps of FIG. 3A-3B) or after the corresponding implantation steps of FIG. 1B or FIG. 2B, a second masking step is performed in which the implanted areas 36 are covered partially by a secondary masking layer 46.

In between the area(s) covered by the masking layer 16 and the area(s) covered by the secondary masking layer 46, openings 48 in the polysilicon layer are formed.

In a subsequent step, the polysilicon layer on the rear surface 11 is etched using the masking layer and the secondary masking layer as etching mask. The tunneling oxide 12 is generally removed in the etching process at the locations where the polysilicon layer is removed, although optionally the tunneling oxide 12 may be conserved. Under the remaining doped polysilicon layer the tunneling oxide 12 is conserved.

As a result, the polysilicon layer at the openings 48 in the mask pattern between the masking layer 16 and the secondary masking layer 46 is removed, such that trenches or gaps are created between the intrinsic polysilicon layer areas 38 and the implanted (polysilicon layer) areas 36 of the first conductivity type. In this manner, electric isolation between the intrinsic areas 38 and the implanted areas 36 is improved. If as shown in e.g. FIG. 3C a polysilicon layer is still present on the front (light-incident) surface of the wafer before this etching step, and if the etching step is executed on both sides of the wafer (e.g. by immersion in a bath) and if the front surface of the wafer is not protected by an etching barrier, in the same etching step the polysilicon layer can be completely or partially removed from the front surface as well. This is shown in FIG. 4A, where the polysilicon layer is completely removed from the front surface of the wafer.

In a next step, the masking layer 16 and the secondary masking layer 46 are removed so as to expose the intrinsic polysilicon layer areas 38 and the implanted (polysilicon layer) areas 36.

Finally, in a subsequent step, the in-diffusion process is carried out in which the silicon substrate 10 is at elevated temperature and is exposed on all sides to the impurity source comprising impurities of the second conductivity type.

In the areas 38 of the intrinsic polysilicon layer that are exposed during the diffusion process and were not exposed during the ion-implantation with impurities of the first conductivity type, doped areas of the second conductivity type are created. Also, the impurities in the implanted areas 36 are activated in such a way that doped areas 36 of the first conductivity type are formed.

In addition, in the bottom of the trenches 48, secondary doped areas 50 of second conductivity type are formed by the diffusion process.

It is noted that in an embodiment, only a portion of the etched trenches is exposed to the impurities of second conductivity type and in that portion the secondary doped areas 50 of second conductivity type are formed. The remainder of the etched trenches is either undoped or doped with impurities of the first conductivity type.

On the front surface and edges of the silicon substrate, the doped layer 44 of second conductivity type is formed.

It is noted that in an embodiment, the formation of the doped layer 44 of second conductivity type is avoided on the front surface, or the doped layer 44 of second conductivity type is removed afterwards, resulting in a solar cell with undoped front surface (i.e., a front surface on or in which no doped layer is provided). Methods to accomplish this are known in the art, and include, for example, a single side etch of the front surface after the formation of the doped layer 44 of second conductivity type; a provision of a diffusion blocking layer on the front side before the formation of the doped layer 44 of second conductivity type; or a front-to-front placement of substrates during the formation of the doped layer 44 of second conductivity type which can partially prevent the formation of the doped layer 44 of second conductivity type on the front surface; or, if the polysilicon layer is still present on the front surface of the wafer during the formation of the doped layer 44 of second conductivity type, the polysilicon layer can be completely removed from the front surface by a single side etching step.

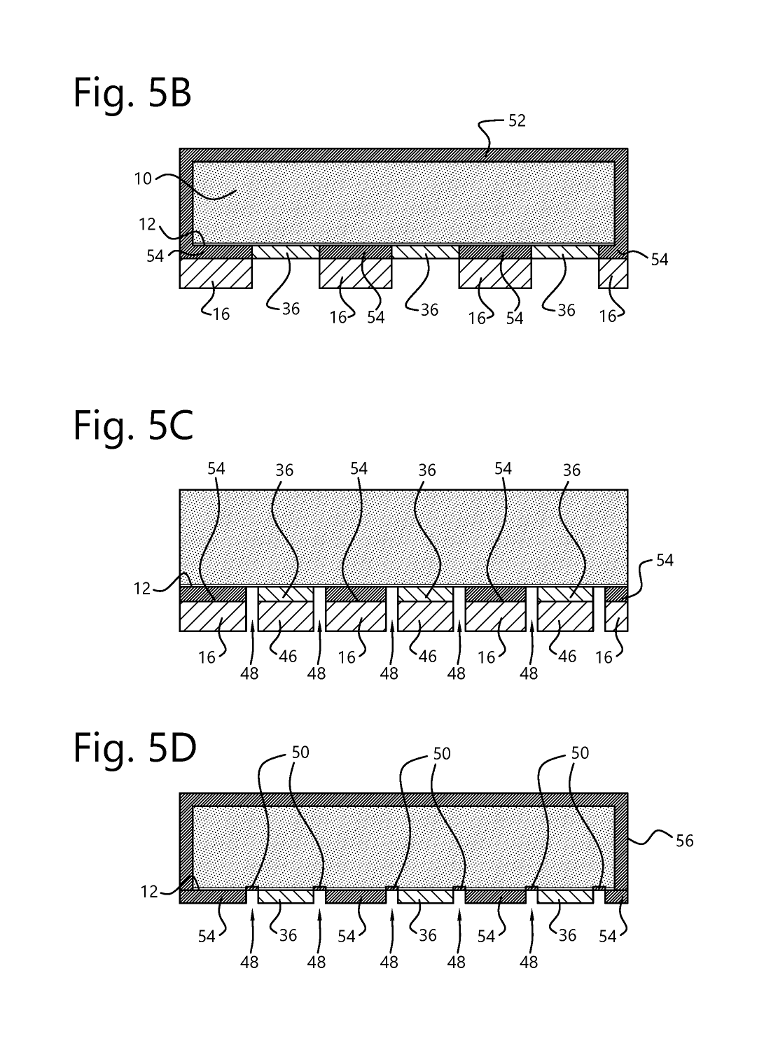

FIGS. 5A-5D show cross-sectional views of a solar cell during manufacturing steps according to an embodiment of the method of the invention.

In FIGS. 5A-5D entities with the same reference number as shown in FIGS. 3A-4B refer to corresponding entities.

FIGS. 5A-5D present an alternative embodiment as compared with the embodiment described in FIGS. 3A-4B.

Similar as in the embodiment as described above, the method involves the manufacturing of an FFE-IBC solar cell.

As shown in FIG. 5A, in an initial step of the manufacturing process the silicon substrate 10 is provided. The silicon substrate 10 has a base conductivity of a first conductivity type.

In a next step, on the rear surface 11 of the silicon substrate 10 a thin film silicon dioxide layer 12 is created to function as a tunneling oxide layer. The thin film silicon dioxide layer 12 has a thickness of 2 nm or less.

In a subsequent step, a polysilicon layer 52 of the second conductivity type is created on all sides of the silicon substrate 10, i.e., front surface, rear surface and edges of the substrate.

According to this embodiment, the deposited polysilicon layer 52 of the second conductivity type is retained on all sides of the silicon substrate during the manufacturing process.

Next, as shown in FIG. 5B, in a first masking step, on the rear surface 11 the patterned masking layer 16 is created. The patterned masking layer 16 has a pattern that exposes areas 36 of the polysilicon layer 52 that are to be doped with first conductivity type impurities, while areas 54 of the second conductivity type in the polysilicon layer remain covered by the masking layer 16.

Subsequently, the patterned and masked rear surface is exposed to an ion-implantation process that exposes the rear surface 11 to the ion beam comprising impurities of the first conductivity type.

As shown in FIG. 5C, after the ion-implantation step to create implanted areas 36 of the first conductivity type in the polysilicon layer 52 of second conductivity type, a second masking step is performed in which the implanted areas 36 are partially covered by a secondary masking layer 46.

In between the area(s) covered by the masking layer 16 and the area(s) covered by the secondary masking layer 46, openings between the pattern of masking layer 16 and the pattern of secondary masking layer 46 are formed.

In a subsequent step, the polysilicon layer on the rear surface 11 is etched using the masking layer 16 and the secondary masking layer 46 as etching mask. The tunneling oxide 12 is generally removed in the etching process at the locations where the polysilicon layer is removed, although optionally the tunneling oxide 12 may be conserved there. Under the remaining doped polysilicon layer the tunneling oxide 12 is conserved.

At the openings between the masking layer 16 and the secondary masking layer 46, the polysilicon layer is removed, such that trenches or gaps 48 are created between the polysilicon layer areas 52 of second conductivity type and the implanted (polysilicon layer) areas 36 of the first conductivity type.

If as shown in e.g. FIG. 3C a polysilicon layer is still present on the front (light-incident) surface of the wafer before this etching step, and if the etching step is executed on both sides of the wafer (e.g. by immersion in a bath) and if the front surface of the wafer is not protected by an etching barrier, in the same etching step the polysilicon layer can be completely or partially removed from the front surface as well.

Next, the masking layer 16 and the secondary masking layer 46 are removed and both the ion-implanted areas 36 of first conductivity type and the areas 54 of second conductivity type polysilicon are now exposed.

Finally, in a subsequent step, the in-diffusion process is carried out in which the silicon substrate 10 is at elevated temperature and is exposed on all sides to the impurity source comprising impurities of the second conductivity type.

In the areas 54 of the intrinsic polysilicon that are exposed during the diffusion process and were not exposed during the ion-implantation with impurities of the first conductivity type, doped areas of the second conductivity type are created. Also, the impurities in the implanted areas 36 are activated in such a way that doped areas 36 of the first conductivity type are formed.

In addition, in the bottom of the trenches 48, secondary doped areas 50 of second conductivity type are formed by the diffusion process.

It is noted that in an embodiment, only a portion of the etched trenches is exposed to the impurities of second conductivity type and in that portion the secondary doped areas 50 of second conductivity type are formed. The remainder of the etched trenches is either undoped or doped with impurities of the first conductivity type.

According to the invention, the in-diffusion is controlled to cause only partial compensation of the areas 36 of first conductivity type, such that the areas 36 of the first conductivity type remain to have the conductivity characteristics of the first conductivity type. In the areas 36 of the first conductivity type the concentration of impurities of the first conductivity type is larger than the concentration of the impurities of the second conductivity type, after the in-diffusion of the impurities of the second conductivity type.

In the areas 54 of the polysilicon layer of second conductivity type, that are exposed during the diffusion process and were not exposed during the ion-implantation with impurities of the first conductivity type, doped areas of the second conductivity type are created.

In addition, in the bottom of the trenches at the location of the gaps 48, secondary doped areas 50 of second conductivity type are formed by the diffusion process.

On the front surface and edges of the silicon substrate, a doped layer 56 of second conductivity type is formed.

It is noted that in an embodiment, the formation of the doped layer 56 of second conductivity type is avoided on the front surface, or the doped layer 56 of second conductivity type is removed afterwards, resulting in a solar cell with an undoped front surface (a front surface on or in which no doped layer is provided). Methods to accomplish this are known in the art, and include, for example, a single side etch of the front surface after the formation of the doped layer 56 of second conductivity type; or provision of a diffusion blocking layer on the front side before the formation of the doped layer 56 of second conductivity type; a front-to-front placement of substrates during the formation of the doped layer 56 of second conductivity type which can partially prevent the formation of the doped layer 56 of second conductivity type on the front surface; or, if the polysilicon layer is still present on the front surface of the wafer during the formation of the doped layer 56 of second conductivity type, the polysilicon layer can be completely removed from the front surface by a single side etching step.

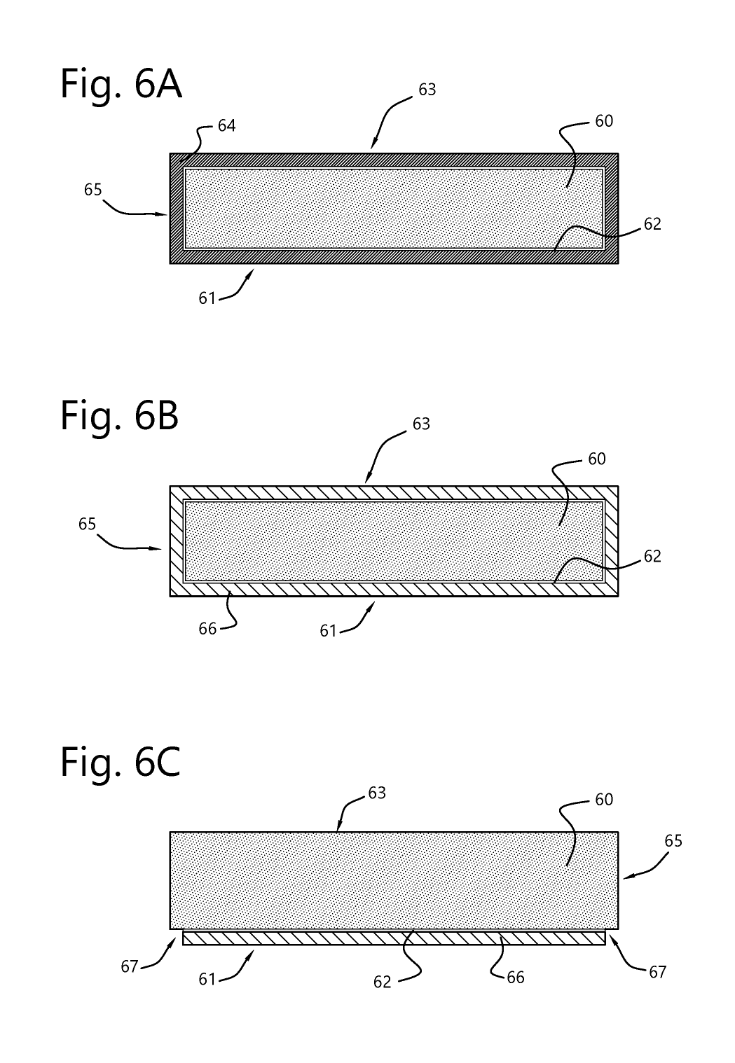

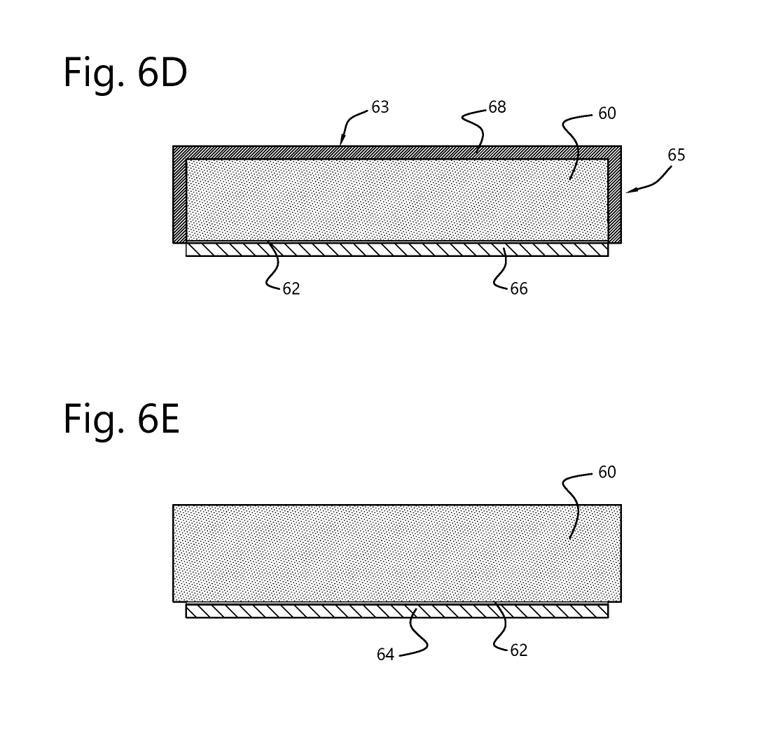

FIGS. 6A-6E show cross-sectional views of a solar cell during manufacturing steps according to an embodiment of the method of the invention.

In this embodiment, the method involves the manufacturing of a solar cell with one type of junction on the front side and the other type of junction on the rear side. Typically, such a solar cell will be completed with a pattern of metal electrodes on both sides (for example the pattern of the metal electrodes is an “H-pattern”).

As shown in FIG. 6A, in an initial step of the manufacturing process the silicon substrate 60 is provided. The silicon substrate 10 has a base conductivity of a first conductivity type.

In a next step, on at least the rear surface 61 of the silicon substrate 60 a thin film silicon dioxide layer 62 is created to function as a tunneling oxide layer. The thin film silicon dioxide layer 62 has a thickness of 2 nm or less.

As shown here, depending on the formation process of the tunneling oxide, the tunneling oxide 62 may be formed on all surfaces of the silicon substrate 60.

In a subsequent step, a polysilicon layer 64 is created on all sides of the silicon substrate 60, i.e., front surface 63, rear surface 61 and edges 65 of the silicon substrate, or at least on the rear surface 61 of the silicon substrate 60.

Such a polysilicon layer 64 can be created by a low-pressure chemical vapor deposition process. In this embodiment, the deposited polysilicon layer 64 is an intrinsic polysilicon layer.

In a first embodiment, the intrinsic polysilicon layer 64 is retained during the following diffusion step.

As shown in FIG. 6B, the silicon substrate as covered by the polysilicon layer 64 is heated to elevated temperature and exposed to a precursor that contains impurities of the first conductivity type. The precursor may be a gas species, a paste, a liquid, a glass or any other source.

During exposure at the elevated temperature, the polysilicon layer becomes a doped polysilicon layer 66 with impurities of the first conductivity type by in-diffusion on all sides of the silicon substrate.

In alternative embodiments, instead of this in-diffusion of impurities of the first kind, layer 64 is on the rear surface 61 exposed to implantation of dopant impurities of the first kind, or layer 64 may be in-situ doped during deposition, i.e. exposed to impurities of the first kind during the deposition process of layer 64.

As shown in FIG. 6C, in a subsequent step the doped polysilicon layer 66 on the front surface 63 of the silicon substrate is removed by a single sided etch process. Additionally, the etching process removes the doped polysilicon layer 66 and the tunneling oxide from the edges 65 and usually also the circumferential part 67 of the rear surface 61 of the silicon substrate 60, although optionally the tunneling oxide may be conserved. On the rear surface 61 of the silicon substrate 60, an area remains covered by the doped polysilicon layer 66 of the first conductivity type. Under the remaining doped polysilicon layer 66, the tunneling oxide 62 is conserved.

The doped polysilicon layer area 66 can be identical to the full area of the rear surface (without taking into account any etching artefact on the rear surface area, such as edges 67 where the doped polysilicon layer 66 has been removed by the etching process).

Finally, as shown in FIG. 6D, the silicon substrate 60 is exposed at elevated temperature to a precursor species comprising impurities of the second conductivity type. In the front surface 63 and the edges 65 of the silicon substrate 60, a diffused layer 68 comprising impurities of the second conductivity type is created, such that the diffused layer 68 has conductivity characteristics of the second conductivity type.

The diffusion process is controlled to cause only partial compensation of the doped polysilicon areas 66 of first conductivity type, such that the doped polysilicon areas 66 of the first conductivity type remain to have the conductivity characteristics of the first conductivity type. In the doped polysilicon areas 66 of the first conductivity type the concentration of impurities of the first conductivity type is larger than the concentration of the impurities of the second conductivity type, after the in-diffusion of the impurities of the second conductivity type.

FIG. 6E shows an optional step of the method. After the all-sided deposition step of the intrinsic polysilicon layer 64, but preceding the step of the all-sided in-diffusion of the impurities of the first conductivity type, the intrinsic polysilicon layer 64 (and tunneling oxide 62) is removed from the front surface 63 and the edges 65 of the silicon substrate 60, by an etching process. Such an additional etching step enhances the gettering at the front surface, during the all-sided in-diffusion, of recombination-active impurities and thereby reduces recombination effects in the solar cell at the front surface and in the bulk of the wafer.

After this additional etching step of the intrinsic polysilicon layer 64 from front surface and edges, the method continues with the all-sided in-diffusion of the impurities of the first conductivity type.

In case only the rear surface 61 is covered by the intrinsic polysilicon layer 64 then during the in-diffusion process of impurities of the first conductivity type, the in-diffusion of impurities of the first conductivity type may take place in the front surface 63 and edges 65 of the silicon substrate 60 and create a doped silicon layer of the first conductivity type in the front surface 63 and the edges 65 of the silicon substrate.

Similar as for the doped polysilicon layer as described above with reference to FIG. 6C, in a subsequent step the doped silicon layer on the front surface 63 of the silicon substrate 60 is removed by a single sided etch process. Additionally, the etching process removes the doped silicon layer and the tunneling oxide from the edges 65 and usually also from the circumferential part 67 of the rear surface 61 of the silicon substrate 60, although optionally the tunneling oxide may be conserved. On the rear surface 61 of the silicon substrate 60, an area remains covered by the doped polysilicon layer 66 of the first conductivity type. Under the remaining doped polysilicon layer 66, the tunneling oxide 62 is conserved.

In an alternative embodiment, after etching the intrinsic polysilicon layer from the front surface 63 and the edges 65 of the silicon substrate 60, the intrinsic polysilicon layer at the rear surface 61 becomes doped by an ion-implantation process. In that case, no doped silicon layer is created on the front surface and the edges. No removal of the doped silicon layer from the front and edge surfaces 63, 65 is then required.

Moreover, it is noted that the first conductivity type can be either n-type or p-type, and the second conductivity type will be opposite to the first conductivity type.

Impurities of n-type can be one or more selected from phosphorus, arsenic and antimony. Impurities of p-type can be one or more selected from boron, aluminium, gallium and indium.

According to an embodiment, the concentration of impurities of the first conductivity type is about 2×10²⁰ cm⁻³ or larger, and the concentration of impurities of the second conductivity type is about 1×10²⁰ cm⁻³ or less.

Additionally, or alternatively, the ratio between the concentration of impurities of the first conductivity type and the concentration of impurities of the second conductivity type can be 1.4 or larger.

It will be appreciated that in each of the embodiments as described above, additional processing steps are required such as the provision of an anti-reflection coating and a contacting structure (metallisation).

The embodiments of solar cells as described above, can be finished with application of front and optionally rear antireflective coatings and metal contacts. It is favorable to cover the polysilicon layer with a layer that provides hydrogen to the thin dielectric layer between the polysilicon layer and the substrate to improve passivation. For example, hydrogen-rich silicon nitride (e.g. deposited by PECVD) or hydrogen-rich silicon oxynitride can be used, or a metal layer such as aluminium which provides hydrogen upon a thermal anneal.

In addition or alternatively, it is favorable to deposit layers that provide hydrogen or act as a diffusion barrier to hydrogen (hydrogen blocking layer) on both sides of the wafer, to enclose the hydrogen and cause more effective hydrogen supply to the interface between the polysilicon and the wafer. It was found in the cell processing according to the invention that providing such layers on only one side of the wafer is less effective for improvement of the passivation than providing them on both sides. It was found that a hydrogen supplying layer on the side opposite to where the polysilicon layer is located can be effective if combined with a hydrogen blocking layer on the polysilicon layer side. Firing (a short thermal anneal of several seconds to minutes at a temperature in the range of about 600° C.-900° C.) can be helpful to supply more hydrogen to the polysilicon/wafer interface.

A beneficial variation of the use of the invention combines a first solar cell with a front side polysilicon passivated contact layer, with another solar cell that has a higher bandgap than crystalline silicon and which is located in front of (i.e., on the light incident side of) the first solar cell. In this way advantages are obtained for the performance of the first solar cell, due to the very good front surface passivation, and the cost of production of the first solar cell is reduced, due to the absence of a need to thin or remove the front side polysilicon layer, while the disadvantage of the short wavelength light absorption in the front side polysilicon layer and resulting current loss is mitigated by the absorption of the short wavelength light in the other solar cell. FIG. 3C is an example of the structure that can be well used for such a first solar cell.

Furthermore, it will be appreciated that the method provides the manufacturing of a solar cell based on a silicon substrate with a front surface and a rear surface, in which the solar cell comprises on at least the rear surface a polysilicon layer with at least one doped area of the first conductivity type covering an area part of the polysilicon layer. The solar cell comprises on the front surface a doped layer of the second conductivity type opposite to the first conductivity type. A tunnelling oxide layer is provided between the polysilicon layer and the rear surface of the substrate. The at least one doped area of the first conductivity type comprises first impurity species of the first conductivity type and second impurity species of the second conductivity type, in which a concentration of the first impurity species is larger than a concentration of the second impurity species and the at least one doped area of the polysilicon layer on the rear surface has conductivity of the first conductivity type.

In the description as mentioned above, the application and/or use of a thin film silicon dioxide layer, or a tunneling oxide layer, is described. It should be understood that the silicon dioxide layer or tunneling oxide layer can be replaced by another thin film barrier layer that has a low interface recombination velocity at the interface with the silicon substrate, and that in combination with the doped polysilicon layer provides good conductance for majority carriers (majority with respect to the type of the doped polysilicon) and low conductance for minority carriers. Such layers have been described in literature, e.g., a relatively thicker silicon oxide layer between 2 and 3 nm thick that is perforated by pinholes, or a nitrogen-containing silicon oxide layer, or a silicon nitride layer with a percolation path for majority carriers. For example, a relatively thicker silicon oxide layer between 2 and 3 nm with pinholes is described in U. Römer et al, IEEE Journal of Photovoltaics 5, 507-514 (2015); the use of a nitrogen-containing silicon oxide layer is described in US2014/01660189; the use of a silicon nitride or silicon nitride/silicon oxide double interfacial layer with a percolation path for majority carriers is described in D. Yan et al, Phys. Status Solidi RRL, 1-5 (2015)/DOI 10.1002/pssr.201510325

Additionally, in the description above, the silicon substrate has a base conductivity (base doping) of the first conductivity type. The skilled in the art will appreciate that according to the invention the base doping type of the substrate is to a certain extent arbitrary. Thus, the silicon substrate can alternatively have a base conductivity of the second conductivity type. In the latter case, the front surface doped layer of second conductivity type will then be a front surface field layer.

According to an aspect, the invention relates to a method for manufacturing a front floating emitter or front surface field type solar cell comprising:—providing a silicon substrate of either a first or a second conductivity type respectively with a front surface and a rear surface;—creating a tunneling oxide layer on at least a rear surface of the silicon substrate;—depositing a polysilicon layer on at least the rear surface;—creating at least one doped area of the first conductivity type in an area part of the polysilicon layer on the rear surface, by exposing the area part to impurity species of the first conductivity type;—forming in or on the front surface a doped layer of the second conductivity type based on exposing the front and rear surfaces of the substrate to impurity species of the second conductivity type that is opposite to the first conductivity type, in a manner that in the area part of the polysilicon layer on the rear surface, a concentration of the impurity of the first conductivity type is larger than a concentration of the impurity of the second conductivity type, and the area part of the polysilicon layer on the rear surface has conductivity of the first conductivity type.

Several benefits of the invention will apply to both polarities as base conductivity. Only the benefits of a front floating emitter will apply when the substrate doping type is opposite to the doping type of the front junction (be it diffused into the wafer surface or the doping type of a front side polysilicon layer).

As described above, masked ion implantation is used as a local doping process. However, the skilled in the art will appreciate that alternative masked or patterned doping processes can be used. For example, masked diffusion from a gas phase can be applied: i.e., instead of an implantation barrier a dopant diffusion barrier is applied, in the same pattern. Or patterned application of a dopant source is applied: for example a dopant glass is applied and patterned as the inverse of the implantation barrier pattern, or a dopant source is printed on the rear surface in a pattern which is the inverse of the implantation barrier. Such masked doping processes can be applied as alternative for masked ion-implantation.

In some embodiments, the method may comprise that in the step of forming in or on the front surface a doped layer of the second conductivity type based on exposing the front and rear surfaces of the substrate to impurity species of a second conductivity type, an imperfect blocking of at a least a portion of the area part of the polysilicon layer on the rear surface is carried out so as to reduce the diffusion of impurity of second conductivity type in the area part with impurities of the first conductivity type.

Such imperfect blocking could comprise that during the exposure to the impurity species of the second conductivity type, the silicon substrate is positioned with the polysilicon layer of the first conductivity type “back-to-back” with the polysilicon layer of the first conductivity type of another silicon substrate.

Alternatively, such imperfect blocking could comprise that a layer is provided on the area part with impurities of the first conductivity type. For example, in an embodiment where the doping process of at least the polysilicon layer on the rear surface with impurities of the first conductivity type is implemented by a gas-phase diffusion process, a glassy capping layer may be created on the polysilicon layer during this doping process. By leaving such a glassy layer on at least a portion of the polysilicon layer on the rear surface this glassy layer may provide imperfect local blocking of in-diffusion of impurities of the second conductivity type on the rear surface. As another example, in an embodiment where the doping process of at least the polysilicon layer on the rear surface with impurities of the first conductivity type is implemented by a locally applied dopant source, a glassy capping layer may be created on the polysilicon layer from this dopant source during this doping process. By leaving such a local glassy layer on the rear surface this glassy layer may provide imperfect local blocking of in-diffusion of impurities of the second conductivity type on the rear surface. The invention allows that such local imperfect blocking layers are acceptable and there is no need for additional provision of a higher quality dedicated diffusion barrier layer. This reduces manufacturing cost.

In some embodiments the method provides that instead of creating a polysilicon layer, a polycrystalline layer of a mixture of silicon and one or more other main elements is created. For example, the polycrystalline layer may consist of a mixture of silicon with oxygen, or a mixture of silicon with carbon, optionally with one or more additional elements in the mixture.

It is noted that the features of the solar cell as shown in the drawings are schematic and not drawn to scale.

The invention has been described with reference to some embodiments. Obvious modifications and alterations will occur to others upon reading and understanding the preceding detailed description. It is intended that the invention be construed as including all such modifications and alterations insofar as they come within the scope of the appended claims.

1. A method for manufacturing a solar cell based on a silicon substrate (10; 60) with a front surface (13; 63) and a rear surface (11; 61), comprising:
on at least the rear surface a polysilicon layer with at least one doped area of a first conductivity type (20; 28; 36; 66) in an area part of the polysilicon layer;
on the front surface a doped layer of a second conductivity type (23; 40; 44; 56; 68) opposite to the first conductivity type;
the method comprising:
providing a silicon substrate of either the first conductivity type or the second conductivity type and having a front surface and a rear surface;
creating a tunneling oxide layer (12;62) on at least a rear surface of the silicon substrate;
depositing a polysilicon layer (14; 26; 34; 52; 64) on at least the rear surface;
creating at least one doped area of the first conductivity type in an area part of the polysilicon layer on the rear surface, by exposing the area part to impurity species of the first conductivity type;
forming in or on the front surface a doped layer of the second conductivity type based on exposing the front and rear surfaces of the substrate to impurity species of a second conductivity type opposite to the first conductivity type, in a manner that
in the area part of the polysilicon layer on the rear surface, the polysilicon layer comprises impurities of the first conductivity type and impurities of the second conductivity type, in which a concentration of the impurity of the first conductivity type is larger than a concentration of the impurity of the second conductivity type, and
the area part of the polysilicon layer on the rear surface has conductivity of the first conductivity type.

2. The method according to claim 1, wherein in the area part of the polysilicon layer on the rear surface, the concentration of the impurity species of the first conductivity type is partially compensated by the concentration of the impurity species of the second conductivity type.

3. The method according to claim 1 or 2, wherein in the deposition step of the polysilicon layer on the at least the rear surface, an intrinsic polysilicon layer is deposited.

4. The method according to any one of claims 1-3, wherein during the deposition step of the polysilicon layer on the at least the rear surface, a doped polysilicon layer of the second conductivity type is deposited.

5. The method according to any one of claims 1-3, wherein during the deposition step of the polysilicon layer on the at least the rear surface, a polysilicon layer comprising impurities of the second conductivity type is deposited.

6. The method according to claim 4 or 5, wherein after the deposition of the doped polysilicon layer of the second conductivity type or the polysilicon layer comprising impurities of the second conductivity type, but preceding the creation of the doped areas of the first conductivity type in the area part of the polysilicon layer on the rear surface,
the method comprises:
providing a masking layer area (16) on the rear surface that exposes only the area part of the polysilicon layer with a remainder part of the rear surface being covered by the masking layer area,
and the creation of the doped areas of the first conductivity type in the area part of the polysilicon layer on the rear surface is performed in a manner that in the exposed area part of the polysilicon layer on the rear surface,
a concentration of the impurity of the first conductivity type by exposing the area part to impurity species of the first conductivity type is larger than a concentration of the impurity of the second conductivity type originating from the doped polysilicon layer of the second conductivity type.

7. The method according to claim 6, wherein
after the provision of the masking layer and
after the creation of the doped areas of the first conductivity type in the area part of the polysilicon layer on the rear surface,
but preceding the formation in the front surface of the doped layer of the second conductivity type,
the method additionally comprises:
masking (46) partially the doped areas of the first conductivity type and etching trenches (48) in the rear surface of the substrate between the masking layer area and the masked doped area of first conductivity type.

8. The method according to claim 7, in which the front surface of the substrate is covered at least partially by the polysilicon layer and wherein the method further comprises etching of the polysilicon layer from at least a part of the front surface while etching the trenches in the rear surface.

9. The method according to claim 8, further comprising: exposing at least a portion of the etched trenches to the impurity species of the second conductivity type and forming in the exposed portion of the etched trenches a doped layer of the second conductivity type (50).

10. The method according to claim 9, further comprising simultaneously forming a doped layer of the second conductivity type in the front surface.

11. The method according to claim 9, further comprising simultaneous formation of a doped layer of the first conductivity type in the front surface.

12. The method according to claim 1, wherein the formation of the doped layer of the second conductivity type in the front surface (63) includes the formation of the doped layer of the second conductivity type on edges (65) of the silicon substrate.

13. The method according to any one of the preceding claims 1-12, wherein the area part of the rear surface is substantially equal to the rear surface area of the silicon substrate.

14. The method according to any one of the preceding claims 1-12, wherein the area part of the rear surface is a patterned area portion.

15. The method according to claim 14, wherein during the deposition step of the polysilicon layer on the at least the rear surface, a doped polysilicon layer of the second conductivity type is deposited, and
the patterned area portion comprises a number of doped areas of first conductivity type, which are interdigitated by intermediate doped areas of the second conductivity type.

16. The method according to any one of preceding claims 1-15, wherein the step of creating at least one doped area of the first conductivity type in the area part of the polysilicon layer on the rear surface comprises ion-implantation of impurities of the first conductivity type in the area part of the polysilicon layer on the rear surface.

17. The method according to any one of preceding claims 1-15, wherein the step of creating at least one doped area of the first conductivity type in the area part of the polysilicon layer on the rear surface comprises diffusion of impurities of the first conductivity type from a first gas phase containing impurities of the first conductivity type into the area part of the polysilicon layer on the rear surface.

18. The method according to claim 17, wherein only the rear surface or only a portion of the rear surface is exposed to the first gas phase containing impurities of the first conductivity type.

19. The method according to claim 1, wherein the step of creating the at least one doped area of the first conductivity type in the area part of the polysilicon layer on the rear surface, by exposing the area part to impurity species of the first conductivity type is performed simultaneously with the step of depositing the polysilicon layer on at least the rear surface.

20. The method according to any one of preceding claims 1-19, wherein the step of exposing the front and rear surfaces of the substrate to impurity species of the second conductivity type comprises diffusion of impurities of the second conductivity type from a second gas phase containing impurities of the second conductivity type.

21. The method according to any one of the preceding claims 1-18, wherein the step of forming in the front surface a doped layer of the second conductivity type based on exposing the front and rear surfaces of the substrate to impurity species of the second conductivity type comprises deposition of a compound containing the impurity species of the second conductivity type from a third gas phase.

22. The method according to any one of preceding claims 1-21, wherein the first conductivity type is n-type, and the second conductivity type is p-type.

23. The method according to claim 22, wherein the impurity species of the first conductivity type is one selected from phosphorus, arsenic and antimony.

24. The method according to claim 22 or 23, wherein the impurity species of the second conductivity type is one selected from boron, aluminium, gallium or indium.

25. The method according to any one of the preceding claims 1-24, wherein the concentration of impurities of the first conductivity type is about 2×10²⁰/cm³ or larger, and the concentration of impurities of the second conductivity type is about 1×10²⁰/cm³ or less.

26. The method according to claim 25, wherein the ratio between the concentration of impurities of the first conductivity type and the concentration of impurities of the second conductivity type is 1.4 or larger.

27. A solar cell based on a silicon substrate (10; 60) with a front surface (13; 63) and a rear surface (11; 61), comprising:
on at least the rear surface a polysilicon layer with at least one doped area of a first conductivity type (20; 28; 36; 66) in an area part of the polysilicon layer;
on the front surface a doped layer of a second conductivity type (23; 40; 44; 56; 66) opposite to the first conductivity type;
a tunneling oxide layer (12; 62) between the polysilicon layer and the rear surface of the silicon substrate;
the polysilicon layer in the at least one doped area of the first conductivity type comprising first impurity species of the first conductivity type and second impurity species of the second conductivity type, in which a concentration of the first impurity species is larger than a concentration of the second impurity species and the at least one doped area of the polysilicon layer on the rear surface has a conductivity of the first conductivity type.

28. The solar cell according to claim 27, wherein in the area part of the polysilicon layer on the rear surface, the concentration of the impurity of the first conductivity type is partially compensated by the concentration of the impurity of the second conductivity type.

29. The solar cell according to claim 27 or claim 28, further comprising a doped layer of the second conductivity type on edges (65) of the silicon substrate (60).

30. The solar cell according to any one of preceding claims 27-29, wherein the area part of the rear surface is substantially equal to the rear surface area of the silicon substrate.

31. The solar cell according to any one of preceding claims 27-29, wherein the rear surface comprises a patterned area portion comprising said at least one doped area of the first conductivity type (20; 28; 36), and at least one doped area of the second conductivity type (24; 30; 42; 38; 54) adjacent to said at least one doped area of the first conductivity type.

32. The solar cell according to claim 31, comprising at least one etched trench (48) between the at least one doped area of the first conductivity type and the at least one doped area of the second conductivity type.

33. The solar cell according to claim 32, wherein at least a portion of the surface of the at least one etched trench comprises a doped layer of the second conductivity type (50).

34. The solar cell according to claim 32, wherein a remainder portion of the surface of the at least one etched trench is either intrinsic or comprises a doped layer of the first conductivity type.

35. The solar cell according to any one of the preceding claims 27-34, wherein the silicon substrate has a base conductivity of either first conductivity type or second conductivity type.

36. A front emitter type or front surface field type solar cell based on a silicon substrate (10; 60), manufactured by a method according to any one of the preceding claims 1-26.

37. A solar panel comprising either at least one solar cell according to any one of the claims 27-36, or at least one solar cell manufactured by a method according to any one of the claims 1-26.
